(19) United States
(12) Patent Application Publication
(10) Pub. No.: US 2012/0313915 A1
(43) Pub. Date: Dec. 13, 2012

(54) THIN-FILM TRANSISTOR (TFT) ARRAY AND LIQUID CRYSTAL DISPLAY (LCD) PANEL THEREOF

(75) Inventor: Shiqi Li, Shenzhen (CN)

(73) Assignee: Shenzhen China Star Optoelectronics Technology Co., Ltd., Shenzhen (CN)

(21) Appl. No.: 13/258,798

(22) PCT Filed: Jun. 20, 2011
(86) PCT No.: PCT/CN11/75937

§ 371 Date: Sep. 22, 2011

(30) Foreign Application Priority Data
Jun. 8, 2011 (CN) 201110151998.1

(51) Int. Cl. G09G 5/00; G02F 1/136; H01L 29/786

(52) U.S. Cl. 345/211; 345/204; 257/368; 349/43; 257/E29.273

(57) ABSTRACT

A thin-film transistor (TFT) array and a liquid crystal display (LCD) panel thereof are described. The TFT array includes a plurality of scan lines, a plurality of data lines, a plurality of pixel units and a plurality of control transistors. When the control transistor turns on and a video signal is transmitted to the pixel unit, the second sub-pixel of another pixel unit is charged. When the gate electrode of the control transistor turns off and the switching transistor of the second sub-pixel of another pixel unit turns on, the second sub-pixel of another pixel unit charges the first sub-pixel of another pixel unit.

### FIELD OF THE INVENTION

The present invention relates to a transistor array and display panel thereof, and more particularly to a thin-film transistor (TFT) array and a liquid crystal display (LCD) panel thereof.

### BACKGROUND OF THE INVENTION

A TFT array is a key component of the liquid crystal display (LCD). FIG. 1 is a schematic structural view of a conventional TFT array 100. The TFT array 100 includes a plurality of pixel units 102, a plurality of scan lines 104 and a plurality of data lines 106.

The pixel units 102 are electrically connected to the scan lines 104 and the data lines 106. Each of the pixel units 102 has a transistor 108, a liquid-crystal capacitor (CLC) 110 and a storage capacitor (CS) 112 wherein the transistor 108 has a gate electrode G, a source electrode S and a drain electrode D. The gate electrode G is connected to the scan line 104, the source electrode S is connected to the data line 106, and the drain electrode D is commonly connected to the CLC 110 and the CS 112 (as shown in FIG. 1) or commonly connected to the common line (not shown).

When a positive voltage is applied to the first scan line (SL1), the thin transistor 108 connected to the first scan line (SL1) turns on so that the pixel electrodes of the CLC 110 are electrically connected to the data lines 106 and the video signal is transmitted to the pixel electrode of pixel unit via the data lines 106 correspondingly for charging the CLC 110 to be a proper voltage level. In other words, the CLC 110 of the pixel unit 102 is charged to drive the liquid crystal molecules within the liquid crystal layer for displaying the image on the LCD panel. Meanwhile, the CSs 112 connected to the data lines 106 are charged wherein the charged CSs 112 are used to maintain the voltage potential of the CLC 110 to be a predetermined value for keeping the voltage potential to be constant in the both terminals of the CLC 110 by the charged CSs 112 before the data lines are updated. Afterwards, a negative voltage is applied to the thin transistor 108 to turn off the thin transistor 108 until the video signal is written to the vertical data lines 106 next time wherein the charges is stored in the CLC 110. The next scan line (SL2) 104 is activated and the video signal is transmitted to the pixel electrodes of the pixel unit P2 102 via the data lines 106 correspondingly.

However, it is required to turn off the thin transistor 108 connected to the scan line (SL1) before the CLC 110 and the CS 112 of the pixel unit P2 102 on the scan line (SL2) are charged, which results in a lot of charging duration. Consequently, there is a need to develop a novel TFT array to solve the aforementioned problem of the long charging duration.

### SUMMARY OF THE INVENTION

One objective of the present invention is to provide a thin-film transistor (TFT) array and a liquid crystal display (LCD) panel thereof to solve the aforementioned problem of the long charging duration. In the TFT array, when the video signal is transmitted to a pixel unit, another pixel unit is charged beforehand. Further, when the gate electrode of the control transistor turns off and a predetermined voltage is applied to the gate line, the charged second sub-pixel of another pixel unit can charge a first sub-pixel for rapid charging the first sub-pixel.

According to the above objective, the present invention sets forth a TFT array and a LCD panel thereof. The TFT array includes a plurality of scan lines, a plurality of data lines, a plurality of pixel units, and a plurality of control transistors. The data lines are disposed and interlaced with the scan lines. Each of the pixel units coupled to one scan line and one data line respectively has a first sub-pixel and a second sub-pixel coupled to the first sub-pixel, the first sub-pixel is coupled to the scan line and the data line, and the second sub-pixel is coupled to the scan line. Each of the control transistors is coupled among the scan line, another data line, one pixel unit and the second sub-pixel of another pixel unit for charging the first sub-pixel of the another pixel unit by the second sub-pixel of the another pixel unit.

In one embodiment, each of the control transistors further includes a gate electrode, a source electrode and a drain electrode. The gate electrode is coupled to the scan line for connecting to the first sub-pixel and the second sub-pixel of the pixel unit. The source electrode is coupled to another data line. The drain electrode is coupled to the second sub-pixel of another pixel unit. When the scan line applies a predetermined voltage to the gate electrode for turning on the control transistor, a video signal is transmitted to the pixel unit and the second sub-pixel of another pixel unit is charged. When the gate electrode of the control transistor turns off and another scan line applies the predetermined voltage to the gate electrode, the second sub-pixel of another pixel unit charges the first sub-pixel of another pixel unit.

In one embodiment, the first sub-pixel further includes a switching transistor, a liquid-crystal capacitor and a storage capacitor. The switching transistor is coupled to another scan line, the data line and the gate electrode of another control transistor. The liquid-crystal capacitor is coupled to the switching transistor. The storage capacitor is coupled to the switching transistor and connected to the liquid-crystal capacitor in parallel manner.

In one embodiment, the second sub-pixel further includes a switching transistor, a liquid-crystal capacitor and a storage capacitor. The switching transistor is coupled to another scan line and the drain electrode of the control transistor. The liquid-crystal capacitor is coupled to the switching transistor and the drain electrode of another control transistor. The storage capacitor is coupled to the switching transistor and the drain electrode of another control transistor wherein the storage capacitor is connected to liquid-crystal capacitor in parallel manner.

In one embodiment, the switching transistor of the first sub-pixel is coupled to the switching transistor of the second sub-pixel.

In another embodiment, the LCD panel has a scan driving module, a data driving module, and a TFT array wherein the scan driving module and the data driving module are used to drive the TFT array. The TFT array includes a plurality of scan lines, a plurality of data lines, a plurality of pixel units, and a plurality of control transistors. The data lines are disposed and interlaced with the scan lines. Each of the pixel units coupled to one scan line and one data line respectively has a first sub-pixel and a second sub-pixel coupled to the first sub-pixel, the first sub-pixel is coupled to the scan line and the data line, and the second sub-pixel is coupled to the scan line. Each of the control transistors is coupled among the scan line, another data line, one pixel unit and the second sub-pixel of another pixel unit for charging the first sub-pixel of the another pixel unit by the second sub-pixel of the another pixel unit.

In one embodiment, each of the control transistors further includes a gate electrode, a source electrode and a drain electrode. The gate electrode is coupled to the scan line for connecting to the first sub-pixel and the second sub-pixel of the pixel unit. The source electrode is coupled to another data line. The drain electrode is coupled to the second sub-pixel of another pixel unit. When the scan line applies a predetermined voltage to the gate electrode for turning on the control transistor, a video signal is transmitted to the pixel unit and the second sub-pixel of another pixel unit is charged. When the gate electrode of the control transistor turns off and another scan line applies the predetermined voltage to the gate electrode, the second sub-pixel of another pixel unit charges the first sub-pixel of another pixel unit.

In one embodiment, the first sub-pixel further includes a switching transistor, a liquid-crystal capacitor and a storage capacitor. The switching transistor is coupled to another scan line, the data line and the gate electrode of another control transistor. The liquid-crystal capacitor is coupled to the switching transistor. The storage capacitor is coupled to the switching transistor and connected to the liquid-crystal capacitor in parallel manner.

In one embodiment, the second sub-pixel further includes a switching transistor, a liquid-crystal capacitor and a storage capacitor. The switching transistor is coupled to another scan line and the drain electrode of the control transistor. The liquid-crystal capacitor is coupled to the switching transistor and the drain electrode of another control transistor. The storage capacitor is coupled to the switching transistor and the drain electrode of another control transistor wherein the storage capacitor is connected to liquid-crystal capacitor in parallel manner.

The TFT array and LCD panel of the present invention utilize the control transistors for turning on or off the control transistors to reduce the charging duration of the pixels. When the scan line applies a predetermined voltage to the gate electrode for turning on the control transistor, the second sub-pixel of another pixel unit is charged by the data line. That is, the data line transmits the video signal to the second sub-pixel of another pixel unit. When the gate electrode of the control transistor turns off and another scan line applies the predetermined voltage to the gate electrode, the second sub-pixel of another pixel unit charges the first sub-pixel of another pixel unit for rapid charging the pixel unit.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic structural view of a conventional TFT array;

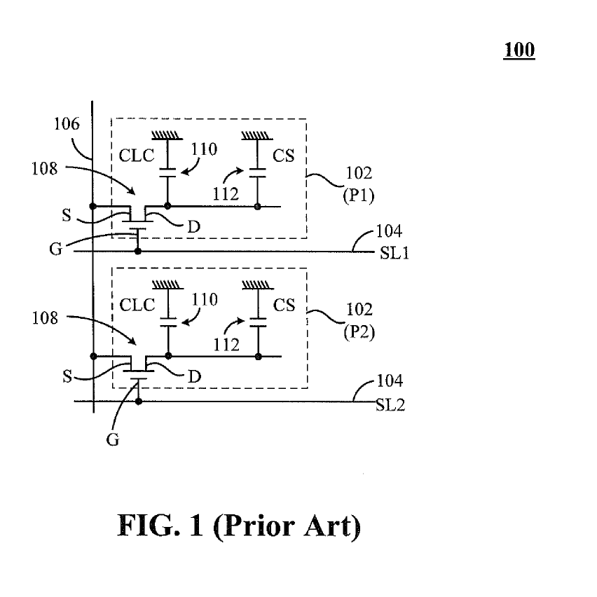

FIG. 2 is a schematic structural view of a TFT array according to one embodiment of the present invention; and

FIG. 3 is a schematic structural view of LCD panel with the TFT array shown in FIG. 2 according to one embodiment of the present invention.

### DETAILED DESCRIPTION OF THE PREFERRED EMBODIMENTS

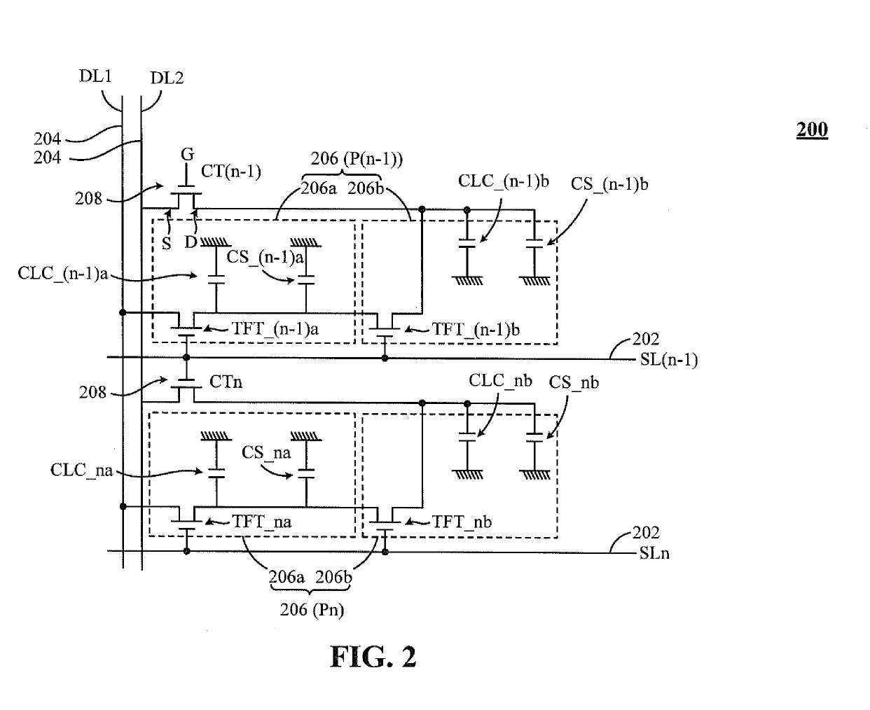

FIG. 2 is a schematic structural view of a thin-film transistor (TFT) array 200 according to one embodiment of the present invention. The TFT array 200 includes a plurality of scan lines 202, a plurality of data lines 204, a plurality of pixel units 206 and a plurality of control transistors 208. The scan lines 202 are disposed and interlaced with the data lines 204. For example, two scan lines SL(n−1), SLn 202 are disposed and interlaced with two data lines DL1, DL2 204. Two pixel units P(n−1), Pn 206 and two control transistors CT(n−1), CTn 208 are exemplarily depicted, but not limited.

The pixel units P(n−1), Pn 206 are disposed in the scan lines SL(n−1), SLn 202 near the interlaced position of the two data lines DL1, DL2 204. The pixel unit P(n−1) 206 is coupled to the scan line SL(n−1) 202 and the data line DL1 204. Each of the pixel units P(n−1) 206 has a first sub-pixel 206a and a second sub-pixel 206b coupled to the first sub-pixel 206a wherein the first sub-pixel 206a is coupled to the scan line SL(n−1) 202 and the data line DL1 204 and the second sub-pixel 206b is coupled to the scan line SL(n−1) 202. Similarly, the pixel unit Pn 206 is coupled to the scan line SLn 202 and the data line DL1 204. Each of the pixel units Pn 206 has a first sub-pixel 206a and a second sub-pixel 206b coupled to the first sub-pixel 206a wherein the first sub-pixel 206a is coupled to the scan line SLn 202 and the data line DL1 204 and the second sub-pixel 206b is coupled to the scan line SLn 202.

The control transistors CT(n−1), CTn 208 are disposed between the pixel units P(n−1), Pn 206 wherein the control transistor CTn 208 is coupled among the scan line SL(n−1) 202, another data line DL2 204, the pixel unit P(n−1) 206 and the second sub-pixel 206b of another pixel unit Pn 206 for charging the first sub-pixel 206a of the pixel unit Pn 206 by the second sub-pixel 206b of the pixel unit Pn 206. Similarly, the control transistor CT(n−1) 208 is coupled among the scan line (not shown), another data line DL2 204, the pixel unit (not shown) and the second sub-pixel 206b of another pixel unit P(n−1) 206 for charging the first sub-pixel 206a of the pixel unit P(n−1) 206 by the second sub-pixel 206b of the pixel unit P(n−1) 206.

Specifically, when the TFT array 200 of the present invention operates, a predetermined voltage (e.g. positive voltage) is applied to the scan line SL(n−1) 202 for turning on the switching transistors TFT_(n−1)a, TFT_(n−1)b of the pixel unit P(n−1) 206. That is, the switching transistors disposed in the scan line SL(n−1) 202 turns on for charging the pixel unit P(n−1) 206. Meanwhile, the predetermined voltage further turns on the control transistor CTn 208 so that the video signal is transmitted to the second sub-pixel 206b of the pixel unit Pn 206 via the data line DL2 204 for charging the second sub-pixel 206b of the pixel unit Pn 206 in advance.

Afterwards, another predetermined voltage (e.g. negative voltage) is applied to the scan line SL(n−1) 202 for turning off the switching transistors TFT_(n−1)a, TFT_(n−1)b and the control transistor CTn 208. The predetermined voltage (e.g. positive voltage) is then applied to the scan line SLn 202 for turning on the switching transistor TFT_na for charging the first sub-pixel 206a of another pixel unit Pn 206 by the data line DL1 204, i.e. transmitting the video signal. Simultaneously, the predetermined voltage turns on the switching transistors TFT_nb for charging the first sub-pixel 206a of another pixel unit Pn 206 by the second sub-pixel 206b of another pixel unit Pn 206. In other words, when the switching transistors TFT_na, TFT_nb turn on, the first sub-pixel 206a of another pixel unit Pn 206 is charged by the second sub-pixel 206b of another pixel unit Pn 206 beforehand besides the first sub-pixel 206a is charged by the data line DL1 204 for the purpose of rapid charging to effectively reduce the charging duration.

Further, the control transistor CTn 208 includes a gate electrode G, a source electrode S and a drain electrode D. The gate electrode G is coupled to the scan line SL(n−1) 202 for connecting to the first sub-pixel 206a and the second sub-pixel 206b of the pixel unit P(n−1) 206. The source electrode S is coupled to another data line DL2 204. The drain electrode D is coupled to the second sub-pixel 206b of another pixel unit Pn 206. When the scan line SL(n−1) 202 applies a predetermined voltage to the gate electrode G for turning on the control transistor CTn 208, the second sub-pixel 206b of another pixel unit Pn 206 is charged by the data line DL2 204. That is, the data line DL2 204 transmits the video signal to the second sub-pixel 206b of another pixel unit Pn 206. When the gate electrode G of the control transistor CTn 208 turns off and another scan line SLn 202 applies the predetermined voltage to the gate electrode G, the second sub-pixel 206b of the another pixel unit Pn 206 charges the first sub-pixel 206a of another pixel unit Pn 206. It should be noted that the detailed descriptions of the control transistor CT(n−1) 208 are omitted since the control transistor CT(n−1) 208 has the same feature as the control transistor CTn 208.

The first sub-pixel 206a of the pixel unit P(n−1) 206 further includes a switching transistor TFT_(n−1)a, liquid-crystal capacitor (CLC) CLC_(n−1)a, and a storage capacitor (CS) CS_(n−1)a. The switching transistor TFT_(n−1)a is coupled to another scan line SL(n−1) 202, the data line DL1 204 and the gate electrode G of another control transistor CTn 208. The liquid-crystal capacitor CLC_(n−1)a is coupled to the switching transistor the TFT_(n−1)a. The storage capacitor (CS) CS_(n−1)a is coupled to the switching transistor TFT_(n−1)a and connected to the liquid-crystal capacitor CLC_(n−1)a in parallel manner. The second sub-pixel 206b of the pixel unit P(n−1) 206 further includes a switching transistor TFT_(n−1)b, liquid-crystal capacitor (CLC) CLC_(n−1)b, and a storage capacitor (CS) CS_(n−1)b. The switching transistor TFT_(n−1)b is coupled to another scan line SL(n−1) 202 and the drain electrode D of the control transistor CTn 208. The liquid-crystal capacitor CLC_(n−1)b is coupled to the switching transistor TFT_(n−1)b and the drain electrode D of another control transistor CT(n−1) 208. The storage capacitor CS_(n−1)b is coupled to the switching transistor TFT_(n−1)b and the drain electrode D of another control transistor CT(n−1) 208 wherein the storage capacitor CS_(n−1)b is connected to liquid-crystal capacitor CLC_(n−1)b in parallel manner.

In one case of the pixel unit P(n−1) 206, the switching transistor TFT_(n−1)a of the first sub-pixel 206a is coupled to the switching transistor TFT_(n−1)b of the second sub-pixel 206b. In another case, the switching transistor TFT_(n−1)b is directly connected to the data line DL1.

Similarly, the first sub-pixel 206a and the second sub-pixel 206b of the pixel unit Pn 206 are similar to the first sub-pixel 206a and the second sub-pixel 206b of the pixel unit P(n−1) 206. The first sub-pixel 206a of the pixel unit Pn 206 further includes a switching transistor TFT_na, liquid-crystal capacitor CLC_na, and a storage storage capacitor CS_na. The switching transistor TFT_na is coupled to another scan line SLn 202, the data line DL1 204 and the gate electrode G of another control transistor (not shown). The liquid-crystal capacitor CLC_na is coupled to the switching transistor the TFT_na. The storage capacitor CS_na is coupled to the switching transistor TFT_na and connected to the liquid-crystal capacitor CLC_na in parallel manner. The second sub-pixel 206b of the pixel unit Pn 206 further includes a switching transistor TFT_nb, liquid-crystal capacitor CLC_nb, and a storage capacitor CS_nb. The switching transistor TFT_nb is coupled to the scan line SLn 202 and the drain electrode D of the control transistor CTn 208. The liquid-crystal capacitor CLC_nb is coupled to the switching transistor TFT_nb and the drain electrode D of another control transistor CTn 208. The storage capacitor CS_nb is coupled to the switching transistor TFT_nb and the drain electrode D of another control transistor CTn 208 wherein the storage capacitor CS_nb is connected to liquid-crystal capacitor CLC_nb in parallel manner.

In one case of the pixel unit Pn 206, the switching transistor TFT_na of the first sub-pixel 206a is coupled to the switching transistor TFT_nb of the second sub-pixel 206b. In another case, the switching transistor TFT_nb is directly connected to the data line DL1.

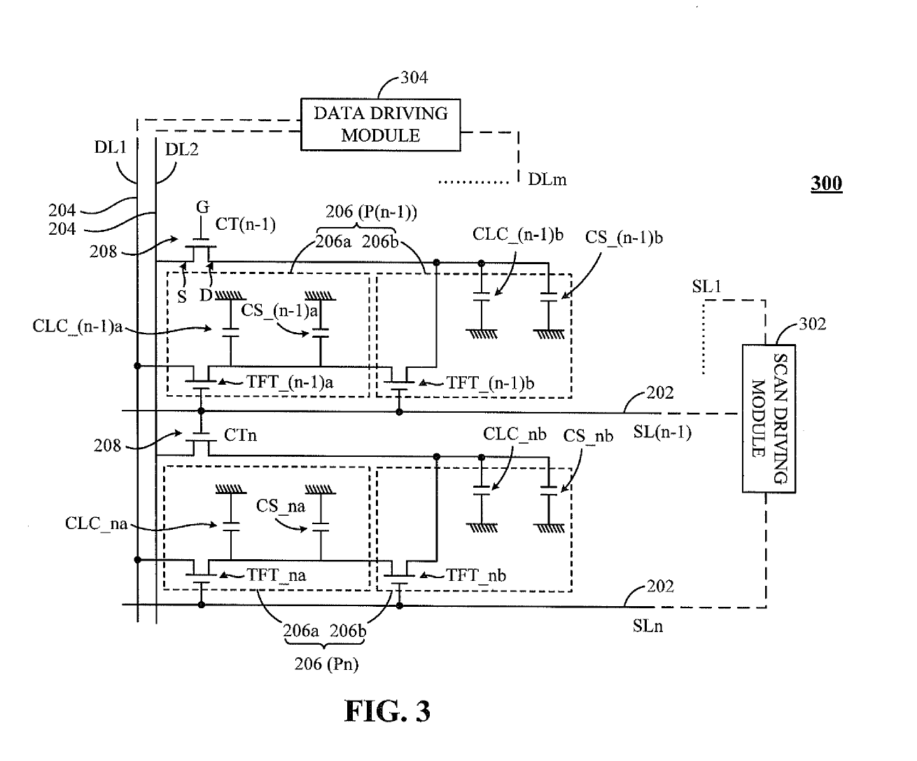

Please refer to FIG. 2 and FIG. 3. FIG. 3 is a schematic structural view of LCD panel 300 with the TFT array 200 shown in FIG. 2 according to one embodiment of the present invention. The LCD panel 300 has a scan driving module 302, a data driving module 304, and a TFT array 200 wherein the scan driving module 302 and the data driving module 304 are used to drive the TFT array 200. That is, the scan driving module 302 applies the predetermined voltage to the scan lines 202 for either turning on or turning off the switching transistors TFT_na, TFT_nb, TFT_(n−1)a and TFT_(n−1)b coupled to the control transistors CTn, CT(n−1) 208 of the scan lines 202. The data driving module 304 transmits the video signal to the pixel units Pn, P(n−1) 206 for charging the CLCs corresponding to the pixel units Pn, P(n−1) 206 to drive the liquid crystal molecules within the liquid crystal layer for displaying the image on the LCD panel.

The TFT array 200 includes a plurality of scan lines 202, a plurality of data lines 204, a plurality of pixel units 206 and a plurality of control transistors 208. The scan lines 202 are disposed and interlaced with the data lines 204. For example, two scan lines SL(n−1), SLn 202 are disposed and interlaced with two data lines DL1, DL2 204. Two pixel units P(n−1), Pn 206 and two control transistors CT(n−1), CTn 208 are exemplarily depicted, but not limited.

The pixel units P(n−1), Pn 206 are disposed in the scan lines SL(n−1), SLn 202 near the interlaced position of the two data lines DL1, DL2 204. The pixel unit P(n−1) 206 is coupled to the scan line SL(n−1) 202 and the data line DL1 204. Each of the pixel units P(n−1) 206 has a first sub-pixel 206a and a second sub-pixel 206b coupled to the first sub-pixel 206a wherein the first sub-pixel 206a is coupled to the scan line SL(n−1) 202 and the data line DL1 204 and the second sub-pixel 206b is coupled to the scan line SL(n−1) 202. Similarly, the pixel unit Pn 206 is coupled to the scan line SLn 202 and the data line DL1 204. Each of the pixel units Pn 206 has a first sub-pixel 206a and a second sub-pixel 206b coupled to the first sub-pixel 206a wherein the first sub-pixel 206a is coupled to the scan line SLn 202 and the data line DL1 204 and the second sub-pixel 206b is coupled to the scan line SLn 202.

The control transistors CT(n−1), CTn 208 are disposed between the pixel units P(n−1), Pn 206 wherein the control transistor CTn 208 is coupled among the scan line SL(n−1) 202, another data line DL2 204, the pixel unit P(n−1) 206 and the second sub-pixel 206b of another pixel unit Pn 206 for charging the first sub-pixel 206a of the pixel unit Pn 206 by the second sub-pixel 206b of the pixel unit Pn 206. Similarly, the control transistor CT(n−1) 208 is coupled among the scan line (not shown), another data line DL2 204, the pixel unit (not shown) and the second sub-pixel 206b of another pixel unit P(n−1) 206 for charging the first sub-pixel 206a of the pixel unit P(n−1) 206 by the second sub-pixel 206b of the pixel unit P(n−1) 206.

Based on the above descriptions, the present invention utilizes the control transistors for either turning on or off the control transistors to reduce the charging duration of the pixels. When the scan line applies a predetermined voltage to the gate electrode for turning on the control transistor, the second sub-pixel of another pixel unit is charged by the data line. That is, the data line transmits the video signal to the second sub-pixel of another pixel unit. When the gate electrode of the control transistor turns off and another scan line applies the predetermined voltage to the gate electrode, the second sub-pixel of another pixel unit charges the first sub-pixel of another pixel unit for rapid charging the pixel unit.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

What is claimed is:

1. A thin-film transistor (TFT) array, comprising:
a plurality of scan lines;
a plurality of data lines, disposed and interlaced with the scan lines;
a plurality of pixel units, wherein each of the pixel units coupled to one scan line and one data line respectively has a first sub-pixel and a second sub-pixel coupled to the first sub-pixel, the first sub-pixel is coupled to the scan line and the data line, and the second sub-pixel is coupled to the scan line; and
a plurality of control transistors, wherein each of the control transistors is coupled among the scan line, another data line, one pixel unit and the second sub-pixel of another pixel unit for charging the first sub-pixel of the another pixel unit by the second sub-pixel of the another pixel unit.

2. The TFT array of claim 1, wherein each of the control transistors further comprises:
a gate electrode coupled to the scan line, connecting to the first sub-pixel and the second sub-pixel of the pixel unit;
a source electrode coupled to another data line; and
a drain electrode coupled to the second sub-pixel of the another pixel unit;
wherein when the scan line applies a predetermined voltage to the gate electrode for turning on the control transistor, a video signal is transmitted to the pixel unit and the second sub-pixel of the another pixel unit is charged, and when the gate electrode of the control transistor turns off and the another scan line applies the predetermined voltage to the gate electrode, the second sub-pixel of the another pixel unit charges the first sub-pixel of the another pixel unit.

3. The TFT array of claim 2, wherein the first sub-pixel further comprises:
a switching transistor coupled to the another scan line, the data line and the gate electrode of another control transistor;
a liquid-crystal capacitor coupled to the switching transistor; and
a storage capacitor coupled to the switching transistor and connected to the liquid-crystal capacitor in parallel manner.

4. The TFT array of claim 3, wherein the second sub-pixel further comprises:
a switching transistor coupled to the another scan line and the drain electrode of the control transistor;
a liquid-crystal capacitor coupled to the switching transistor and the drain electrode of the another control transistor; and
a storage capacitor coupled to the switching transistor and the drain electrode of the another control transistor wherein the storage capacitor is connected to the liquid-crystal capacitor in parallel manner.

5. The TFT array of claim 4, wherein the switching transistor of the first sub-pixel is coupled to the switching transistor of the second sub-pixel.

6. A liquid crystal display (LCD) panel having a scan driving module, a data driving module, and a TFT array wherein the scan driving module and the data driving module are used to drive the TFT array, the TFT array comprising:
a plurality of scan lines;
a plurality of data lines, disposed and interlaced with the scan lines;
a plurality of pixel units, wherein each of the pixel units coupled to one scan line and one data line respectively has a first sub-pixel and a second sub-pixel coupled to the first sub-pixel, the first sub-pixel is coupled to the scan line and the data line, and the second sub-pixel is coupled to the scan line; and
a plurality of control transistors, wherein each of the control transistors is coupled among the scan line, another data line, one pixel unit and the second sub-pixel of another pixel unit for charging the first sub-pixel of the another pixel unit by the second sub-pixel of the another pixel unit.

7. The LCD panel of claim 6, wherein each of the control transistors further comprises:
a gate electrode coupled to the scan line, connecting to the first sub-pixel and the second sub-pixel of the pixel unit;
a source electrode coupled to another data line; and
a drain electrode coupled to the second sub-pixel of the another pixel unit;
wherein when the scan line applies a predetermined voltage to the gate electrode for turning on the control transistor, a video signal is transmitted to the pixel unit and the second sub-pixel of the another pixel unit is charged, and when the gate electrode of the control transistor turns off and the another scan line applies the predetermined voltage to the gate electrode, the second sub-pixel of the another pixel unit charges the first sub-pixel of the another pixel unit.

8. The LCD panel of claim 7, wherein the first sub-pixel further comprises:
a switching transistor coupled to the another scan line, the data line and the gate electrode of another control transistor;
a liquid-crystal capacitor coupled to the switching transistor; and
a storage capacitor coupled to the switching transistor and connected to the liquid-crystal capacitor in parallel manner.

9. The LCD panel of claim 8, wherein the second sub-pixel further comprises:
a switching transistor coupled to the another scan line and the drain electrode of the control transistor;
a liquid-crystal capacitor coupled to the switching transistor and the drain electrode of the another control transistor; and
a storage capacitor coupled to the switching transistor and the drain electrode of the another control transistor, wherein the storage capacitor is connected to the liquid-crystal capacitor in parallel manner.

10. The LCD panel of claim 9, wherein the switching transistor of the first sub-pixel is coupled to the switching transistor of the second sub-pixel.
